(19) United States
(12) Patent Application Publication
(10) Pub. No.: US 2007/0153453 A1
(43) Pub. Date: Jul. 5, 2007

(54) Fully conductive pad for electrochemical mechanical processing

(75) Inventors: You Wang, Cupertino, CA (US); Renhe Jia, Berkeley, CA (US); Stan D. Tsai, Fremont, CA (US); Yongqi Hu, San Jose, CA (US); Zhihong Wang, Santa Clara, CA (US); Jie Diao, San Jose, CA (US); Gerald John Alonzo, Los Gatos, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/327,527

(22) Filed: Jan. 5, 2006

(51) Int. Cl. H05K 5/00; H05K 3/10

(52) U.S. Cl. 361/679; 29/846; 29/847

(57) ABSTRACT

Embodiments of a pad assembly for processing a substrate are provided. The pad assembly includes a plurality of discrete members and a plurality of apertures. Each of the plurality of discrete members include a first conductive layer and a second conductive layer, with an isolation layer therebetween, and a recess for byproduct accumulation. The second conductive layer comprises a plurality of reaction surfaces that are orthogonal to the upper and lower surfaces of the pad assembly.

### BACKGROUND OF THE INVENTION

1. Field of the Invention

Embodiments of the present invention generally relate to a processing apparatus for planarizing or polishing a substrate. More particularly, the invention relates to polishing pad design for planarizing or polishing a semiconductor wafer by electrochemical mechanical planarization.

2. Description of the Related Art

In the fabrication of integrated circuits and other electronic devices on substrates, multiple layers of conductive, semiconductive, and dielectric materials are deposited on or removed from a substrate, such as a semi conductor wafer. As layers of materials are sequentially deposited and removed, the substrate may become non-planar and require planarization, in which previously deposited material is removed from the substrate to form a generally even, planar or level surface. The process is useful in removing undesired surface topography and surface defects, such as rough surfaces, agglomerated materials, crystal lattice damage and scratches. The planarization process is also useful in forming features on the substrate by removing excess deposited material used to fill the features and to provide an even or level surface for subsequent deposition and processing.

Electrochemical Mechanical Planarization (ECMP) is one exemplary process which is used to remove materials from the substrate. ECMP typically uses a pad having conductive properties and combines physical abrasion with electrochemical activity that enhances the removal of materials. The pad is attached to an apparatus having a rotating platen assembly that is adapted to couple the pad to a power source. The apparatus also has a substrate carrier, such as a polishing head, that is mounted on a carrier assembly above the pad that holds a substrate. The polishing head places the substrate in contact with the pad and is adapted to provide downward pressure, controllably urging the substrate against the pad. The pad is moved relative to the substrate by an external driving force and the polishing head typically moves relative to the moving pad. A chemical composition, such as an electrolyte, is typically provided to the surface of the pad which enhances electrochemical activity between the pad and the substrate. The ECMP apparatus may effect abrasive and/or polishing activity from frictional movement while the electrolyte combined with the conductive properties of the pad selectively removes material from the substrate.

Although ECMP has produced good results in recent years, there is an ongoing effort to develop pads with improved polishing qualities combined with optimal electrical properties that will not degrade over time and require less conditioning, thus providing extended periods of use with less downtime for replacement. Inherent in this challenge is the difficulty in producing a pad that will not react with process chemistry, which may cause degradation, or require excessive conditioning.

Maintenance of localized electrical contact to the deposit receiving side of the substrate creates challenges in polarization, especially during residual material removal. Additionally, byproducts of the ECMP process affect the electrochemical reaction surface, which may increase process time and degradation of the pad.

Therefore, there exists a need in the art for a processing article or pad that is adapted for the removal of conductive materials and other materials from the substrate and is designed to overcome these challenges.

### SUMMARY OF THE INVENTION

In one embodiment, a pad assembly for processing a substrate is described. The pad assembly includes a first conductive layer having an upper surface adapted to contact the substrate, a conductive carrier coupled to and disposed below the first conductive layer, a second conductive layer disposed below the conductive carrier with an isolation layer therebetween, wherein the second conductive layer includes a plurality of reaction surfaces that are orthogonal to the upper surface, and a plurality of recesses formed below the second conductive layer.

In another embodiment, a pad assembly for processing a substrate is described having a plurality of discrete members coupled to a base defining a plurality of functional cells therebetween, and a bonding layer to adhere the second conductive layer to the base to define a recess above the base, wherein each of the plurality of discrete members include a first conductive layer adapted to contact the substrate and a second conductive layer separated by an isolation layer with a plurality of recesses formed below the second conductive layer.

In another embodiment, a pad assembly for polishing a substrate is described having a processing surface adapted to contact the substrate. The processing surface includes a plurality of discrete members defining a plurality of functional cells therebetween, wherein each of the plurality of discrete members include a first conductive layer and a second conductive layer with an isolation layer therebetween, and wherein the second conductive layer is comprises a plurality of reaction surfaces that are orthogonal to the processing surface.

In another embodiment, a method of extending electrochemical activity in a processing pad assembly is described. The method includes providing a pad assembly having a first conductive layer, a second conductive layer, and a plurality of functional cells, and providing a recess below the second conductive layer for by-product accumulation from a polishing process.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top view of one embodiment of a processing system.

FIG. 2A is a sectional view of an exemplary ECMP station.

FIG. 2B is an exploded view of one embodiment of a portion of the pad assembly shown in FIG. 2A

FIG. 3 is a schematic side view of a portion of one embodiment of a pad assembly.

FIG. 4 is a schematic side view of a portion of another embodiment of a pad assembly.

FIG. 5A is a top view of another embodiment of a pad assembly.

FIG. 5B is an exploded view of a portion of the processing surface of the pad assembly shown in FIG. 5A.

FIG. 6A is a top view of another embodiment of a pad assembly.

FIG. 6B is an exploded view of a portion of the processing surface of the pad assembly shown in FIG. 6A.

To facilitate understanding, identical reference numerals have been used, where possible, to designate identical elements that are common to the figures.

### DETAILED DESCRIPTION

The words and phrases used in the present invention should be given their ordinary and customary meaning in the art by one skilled in the art unless otherwise further defined. The embodiments described herein may relate to removing material from a substrate, but may be equally effective for electroplating a substrate by adjusting the polarity of an electrical source. Common reference numerals may be used in the Figures, where possible, to denote similar elements depicted in the Figures.

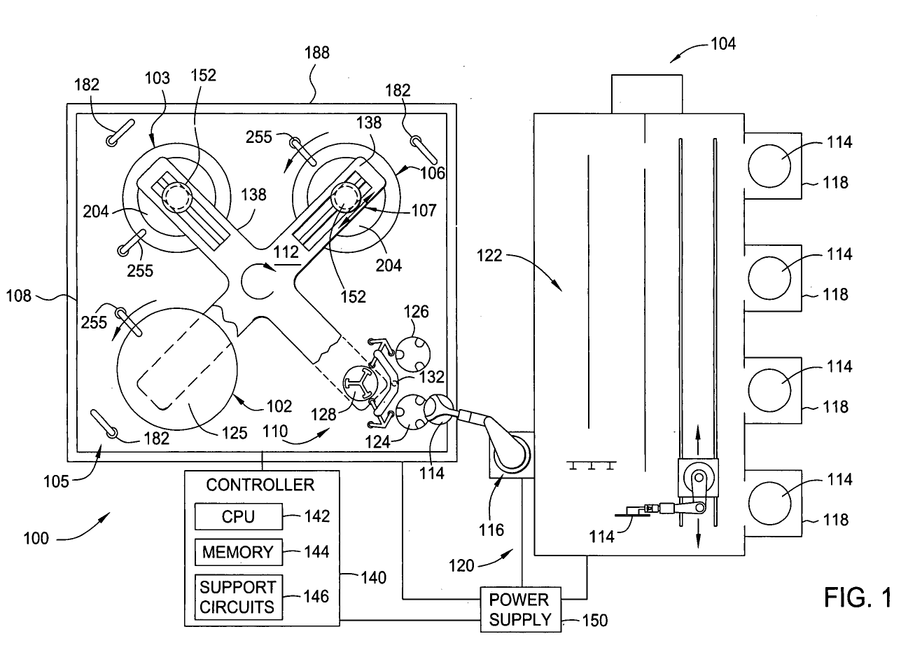

FIG. 1 is a top view of a processing system 100 having a planarizing module 105 that is suitable for electrochemical mechanical polishing and chemical mechanical polishing. The planarizing module 105 includes at least a first electrochemical mechanical planarization (ECMP) station 102, and optionally, at least one conventional chemical mechanical planarization (CMP) station 106 disposed in an environmentally controlled enclosure 188. An example of a processing system 100 that may be adapted to practice the invention is the REFLEXION LK Ecmp™ system available from Applied Materials, Inc. located in Santa Clara, Calif. Other planarizing modules commonly used in the art may also be adapted to practice the invention.

The planarizing module 105 shown in FIG. 1 includes a first ECMP station 102, a second ECMP station 103, and one CMP station 106. It is to be understood that the invention is not limited to this configuration and that all of the stations 102, 103, and 106 may be adapted to use an ECMP process to remove various layers deposited on the substrate. Alternatively, the planarizing module 105 may include two stations that are adapted to perform a CMP process while another station may perform an ECMP process. In one exemplary process, a substrate having feature definitions lined with a barrier layer and filled with a conductive material disposed over the barrier layer may have the conductive material removed in two steps in the two ECMP stations 102, 103, with the barrier layer processed in the conventional CMP station 106 to form a planarized surface on the substrate. It is to be noted that the stations 102, 103, and 106 in any of the combinations mentioned above may also be adapted to deposit a material on a substrate by an electrochemical and/or an electrochemical mechanical plating process.

The exemplary system 100 generally includes a base 108 that supports one or more ECMP stations 102, 103, one or more CMP stations 106, a transfer station 110, conditioning devices 182, and a carousel 112. The transfer station 110 generally facilitates transfer of substrates 114 to and from the system 100 via a loading robot 116. The loading robot 116 typically transfers substrates 114 between the transfer station 110 and an interface 120 that may include a cleaning module 122, a metrology device 104 and one or more substrate storage cassettes 118.

The transfer station 110 comprises at least an input buffer station 124, an output buffer station 126, a transfer robot 132, and a load cup assembly 128. The loading robot 116 places the substrate 114 onto the input buffer station 124. The transfer robot 132 has two gripper assemblies, each having pneumatic gripper fingers that hold the substrate 114 by the substrate's edge. The transfer robot 132 lifts the substrate 114 from the input buffer station 124 and rotates the gripper and substrate 114 to position the substrate 114 over the load cup assembly 128, then places the substrate 114 down onto the load cup assembly 128. An example of a transfer station that may be used is described in U.S. Pat. No. 6,156,124, issued Dec. 5, 2000, entitled “Wafer Transfer Station for a Chemical Mechanical Polisher,” incorporated herein by reference to the extent it is not inconsistent with this application.

The carousel 112 generally supports a plurality of carrier heads 186, each of which retains one substrate 114 during processing. The carousel 112 moves the carrier heads 186 between the transfer station 110 and stations 102, 103 and 106. One carousel that may used is generally described in U.S. Pat. No. 5,804,507, issued Sep. 8, 1998, entitled “Radially Oscillating Carousel Processing System for Chemical Mechanical Polishing,” which is hereby incorporated by reference to the extent it is not inconsistent with this application.

The carousel 112 is centrally disposed on the base 108. The carousel 112 typically includes a plurality of arms 138 and each arm 138 generally supports one of the carrier heads 186. Two of the arms 138 depicted in FIG. 1 are shown in phantom so that the transfer station 110 and a processing surface 125 of ECMP station 102 may be seen. The carousel 112 is indexable such that the carrier head 186 may be moved between stations 102, 103, 106 and the transfer station 110 in a sequence defined by the user.

Generally the carrier head 186 retains the substrate 114 while the substrate 114 is disposed in the ECMP stations 102, 103 or CMP station 106. The arrangement of the ECMP stations 102, 103 and polishing stations 106 on the system 100 allow for the substrate 114 to be sequentially processed by moving the substrate between stations while being retained in the same carrier head 186.

To facilitate control of the polishing system 100 and processes performed thereon, a controller 140 comprising a central processing unit (CPU) 142, memory 144 and support circuits 146 is connected to the polishing system 100. The CPU 142 may be one of any form of computer processor that can be used in an industrial setting for controlling various drives and pressures. The memory 144 is connected to the CPU 142. The memory 144, or computer-readable medium, may be one or more of readily available memory such as random access memory (RAM), read only memory (ROM), floppy disk, hard disk, or any other form of digital storage, local or remote. The support circuits 146 are connected to the CPU 142 for supporting the processor in a conventional manner. These circuits include cache, power supplies, clock circuits, input/output circuitry, subsystems, and the like.

Power to operate the polishing system 100 and/or the controller 140 is provided by a power supply 150. Illustratively, the power supply 150 is shown connected to multiple components of the polishing system 100, including the transfer station 110, the factory interface 120, the loading robot 116 and the controller 140.

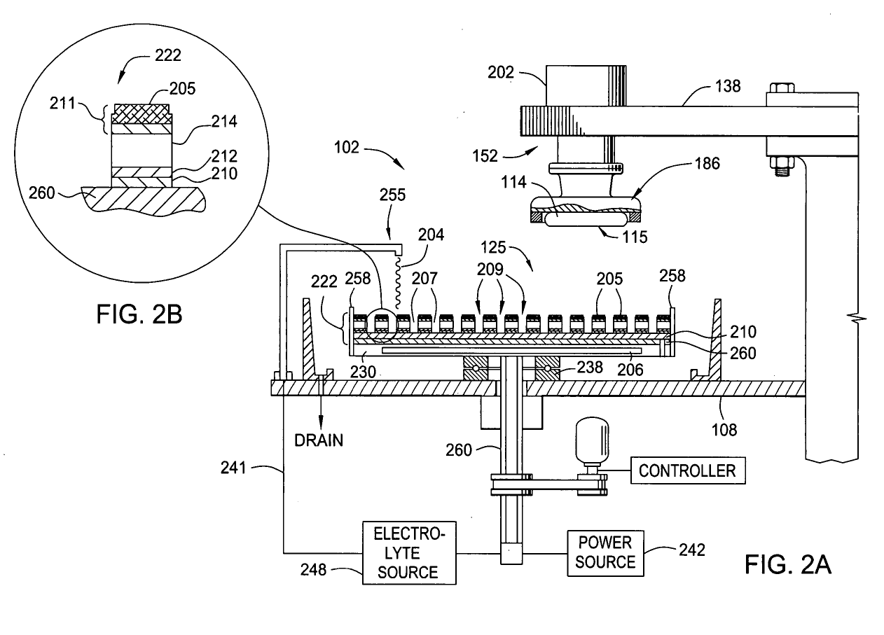

FIG. 2A depicts a sectional view of an exemplary ECMP station 102 depicting a carrier head assembly 152 positioned over a platen assembly 230. The carrier head assembly 152 generally comprises a drive system 202 coupled to a carrier head 186. The drive system 202 may be coupled to the controller 140 (FIG. 1) that provides a signal to the drive system 202 for controlling the rotational speed and direction of the carrier head 186. A processing pad assembly 222 is shown coupled to the platen assembly 230. The processing pad assembly 222 is configured to receive an electrical bias to perform a plating process and/or an electrochemical mechanical polishing/planarizing process. The drive system 202 generally provides at least rotational motion to the carrier head 186 and additionally may be actuated toward the ECMP station 102 such that a deposit receiving side 115 of the substrate 114, retained in the carrier head 186, may be disposed against the pad assembly 222 of the ECMP station 102 during processing. Typically, the substrate 114 and processing pad assembly 222 are rotated relative to one another in an ECMP process to remove material from the deposit receiving side 115 of the substrate 114. Depending on process parameters, the carrier head 186 is rotated at a rotational speed greater than, less than, or equal to, the rotational speed of the platen assembly 230. The carrier head assembly 152 is also capable of remaining fixed and may move in a path indicated by arrow 107 in FIG. 1 during processing. The carrier head assembly 152 may also provide an orbital or a sweeping motion across the processing surface 125 during processing.

In one embodiment, the processing pad assembly 222 may be adapted to releasably couple to an upper surface 260 of the platen assembly 230. The pad assembly 222 may be bound to the upper surface 260 by the use of pressure and/or temperature sensitive adhesives, allowing replacement of the pad assembly 222 by peeling the pad assembly from the upper surface 260 and applying fresh adhesive prior to placement of a new pad assembly 222. In another embodiment, the upper surface 260 of the platen assembly 230, having the processing pad assembly 222 coupled thereto, may be adapted to releasably couple to the platen assembly 230 via fasteners, such as screws.

The platen assembly 230 is typically rotationally disposed on a base 108 and is typically supported above the base 108 by a bearing 238 so that the platen assembly 230 may be rotated relative to the base 108. The platen assembly 230 may be fabricated from a rigid material, such as a metal or rigid plastic, and in one embodiment the platen assembly 230 has an upper surface 260 that is fabricated from or coated with a dielectric material, such as CPVC. The platen assembly 230 may have a circular, rectangular or other plane form and the upper surface 260 may resemble that plane form.

Electrolyte may be provided from the source 248, through appropriate plumbing and controls, such as conduit 241, to nozzle 255 above the processing pad assembly 222 of the ECMP station 102. Optionally, a plenum 206 may be defined in the platen assembly 230 for containing an electrolyte and facilitating ingress and egress of the electrolyte to the pad assembly 222. A detailed description of an exemplary planarizing assembly suitable for using the present invention can be found in United States Patent Publication No. 2004/0163946 (Attorney Docket No. 004100.P10), entitled “Pad Assembly for Electrochemical Mechanical Processing,” filed Dec. 23, 2003, which is incorporated herein by reference to the extent it is not inconsistent with this application.

In the embodiment shown in FIG. 2A, an electrolyte 204 is provided from a nozzle 255. The electrolyte 204 may form a bath that is bounded by a platen lip 258 adapted to contain a suitable processing level of electrolyte 204 while rotating. Alternatively, the electrolyte may be provided by the nozzle 255 continuously or at intervals to maintain a suitable level of electrolyte in the processing pad assembly 222. After the electrolyte has reached its processing capacity and is ready for replacement, the platen assembly 230 may be rotated at a higher rotational speed and the spent electrolyte 311 is released by the action of centrifugal force over the platen lip 258. In another embodiment, the platen assembly 230 is rotated at a higher rotational speed the spent electrolyte is released through perforations in the platen lip 258 that may be opened and closed by an operator or controlled by rotational speed. Alternatively or additionally, spent electrolyte may be released through at least one perforation performing as a drain formed through various layers of the pad assembly 222 and the platen assembly 230.

FIG. 2B is an exploded view of a portion of the pad assembly 222 shown in FIG. 2A. The pad assembly 222 generally includes a plurality of posts or discrete members 205, coupled to a pad base 210. The plurality of discrete members 205 may take the form of posts or extensions extending upward from the pad base 210 and generally include a first conductive layer 211 and a second conductive layer 212 with an isolation layer 214 therebetween to electrically isolate the first and second conductive layers 211, 212.

The discrete members 205 may include any geometrical shape, such as ovals, rectangles, triangles, hexagons, octagons, or combinations thereof. A processing surface 125 is generally defined by an upper portion of each of the discrete members 205 and a plurality of apertures 209. The plurality of apertures 209 are generally defined by the open areas between the plurality of discrete members 205 and each of the plurality of apertures 209 define a functional cell 207 which is configured to receive an electrolyte. Each of the functional cells 207 are adapted to perform as an electrochemical cell when the electrolyte 204 is provided to the pad assembly 222, and a differential electrical bias is applied to the first conductive layer 211 and the second conductive layer 212. In one embodiment, the plurality of apertures 209, or the plurality of functional cells 207, define an open area between about 5 percent to about 90 percent, for example, between about 20 percent to about 70 percent.

The isolation layer 214 may be made of a soft material that is configured to provide compressibility to the pad assembly 222. The isolation layer may be made of a polymer material, such as an open cell foamed polymers, closed cell foamed polymers, a MYLAR® material, heat activated adhesives, or combinations thereof. The isolation layer 214 may have a hardness of about 60 Shore A to about 100 Shore A.

The pad assembly 222 may be formed by compression molding, male/female punch/die, or other methods known in the art to form the plurality of apertures 209 and the plurality of discrete members 205. Each of the plurality of apertures 209 may be formed at least to the upper surface of the pad base 210. In this embodiment, the pad base 210 is solid and configured to retain the electrolyte until released. Alternatively or additionally, at least one of the plurality of apertures 209 may be extended through the pad base 210 and the upper surface 260 (not shown) of the platen assembly 230 to allow electrolyte to be in communication with the plenum 206. In another embodiment, the plurality of discrete members 205 and the plurality of apertures 207 may be formed at least to the pad base 210, and the processing surface 125 may be embossed to form an irregular surface on the upper surface of the plurality of discrete members 205. Patterns of channels or grooves may be formed in the upper surface of the plurality of discrete members 205 to aid in electrolyte transportation along the processing surface 125 and facilitate polishing of the substrate 114. Other patterns may include a plurality of small protrusions adjacent shallow depressions in the processing surface 125. The protrusions may take any geometrical form, such as ovals, circles, rectangles, hexagons, octagons, triangles, or combinations thereof and may be formed by compression molding and/or embossment of the processing surface 125. Alternatively, the upper surfaces of each of the plurality of discrete members 205 may be substantially flat or planar having negligible raised or lowered portions on the processing surface 125.

The upper surface of each of the plurality of discrete members 205 are made from a conductive material configured to communicate an electrical bias from an upper portion of the pad assembly 222 to the deposit receiving side 115 of the substrate 114 during processing. In one embodiment, the upper surface of each of the plurality of discrete members 205 may be fabricated from a conventional polishing material, such as polymer based pad materials compatible with the process chemistry, examples of which include polyurethane, polycarbonate, fluoropolymers, PTFE, PTFA, polyphenylene sulfide (PPS), or combinations thereof. The conventional polishing material may be coated, doped, or impregnated with a process compatible conductive material and/or particles. Alternatively, the conductive material may be a conductive polymer, such as a conductive or dielectric filler material disposed in a conductive polymer matrix or a conductive fabric. In one embodiment, the conductive material is a polymer matrix having a plurality of conductive particles disposed therein. The conductive particles may be particles made of copper, tin, nickel, gold, silver, or combinations thereof. The conductive particles may exhibit a hardness less than, greater than, or equal to that of the conductive material on the deposit receiving side 115 of the substrate 114. Alternatively or additionally, abrasive particles may be interspersed within the conductive or dielectric polymer materials to enhance removal of conductive and residual material from the deposit receiving side 115 of the substrate 114. Examples of abrasive particles that may be used are conductive metals and/or ceramic materials, such as aluminum, ceria, oxides thereof and derivatives thereof, and combinations thereof.

In one embodiment, the pad base 210 may be an article support layer that provides additional rigidity to the pad assembly 222. The pad base 210 may be fabricated from polymeric materials, for example, polyurethane and polyurethane mixed with fillers, polycarbonate, polyphenylene sulfide (PPS), ethylene-propylene-diene-methylene (EPDM), TEFLON® polymers, or combinations thereof, and other polishing materials used in polishing substrate surfaces, such as open or closed-cell foamed polymer, elastomers, felt, impregnated felt, plastics, and like materials compatible with the processing chemistries. In one embodiment, the pad base 210 is a polyethylene terephthalate (PET) material, and derivatives thereof, such as a MYLAR® polymer sheet. The PET material has a density between about 1.25 grams/cm² to about 1.45 grams/cm² and a modulus of elasticity between about 700,000 psi to about 760,000 psi. The pad base 210 material may have a hardness of about 30 Shore A to about 90 Shore A, and is typically harder than the isolation layer 214.

In a typical ECMP process, the substrate 114 is controllably urged against the processing surface 125 of the pad assembly 222, and a potential difference or bias is applied between the second conductive layer 212, performing as a cathode, and the deposit receiving side 115 of the substrate 114, which acts as the anode when in contact with the first conductive layer 211. The application of the bias allows removal of conductive and other materials, such as copper-containing materials and tungsten-containing materials, from the deposit receiving side 115 of the substrate 114. Examples of suitable parameters for ECMP that may be used are disclosed in U.S. Patent Publication No. 2004/0020789 (Attorney Docket No. 003100.P5), entitled “Conductive Polishing Article for Electrochemical Mechanical Polishing,” filed Jun. 6, 2003, which is incorporated herein by reference to the extent the application is not inconsistent with this application.

It can be appreciated by those skilled in the art that polarity could be altered and material could be deposited on the deposit receiving side 115. For example, the deposit receiving side 115 could be biased by the first conductive layer 211 to perform as a cathode, and the second conductive layer 212 could perform as an anode, and a plating solution could be delivered to the pad assembly 222.

As the deposit receiving side 115 of the substrate 114 may contain conductive material to be removed from the substrate 114, fewer biasing contacts for biasing the deposit receiving side 115 are required. As the conductive material to be removed from the deposit receiving side 115 of the substrate 114 comprises isolated islands of conductive material disposed on the deposit receiving side 115, more biasing contacts for biasing the deposit receiving side 115 are required. Embodiments of the processing pad assembly 222 suitable for residual removal of material from the deposit receiving side 115 of the substrate 114 may generally include a processing surface 125 that is substantially conductive. In one embodiment, excess conductive material is removed from the deposit receiving side 115 of the substrate 114 wherein a conductive, abrasive-free processing surface 125 provides a suitable array and distribution of biasing contacts, and the residual material is removed by an electrochemical mechanical removal process provided by the conductive processing surface 125. In another embodiment, the processing surface 125 may further include abrasive particles as described herein to enhance mechanical material removal.

Processing Pad Articles

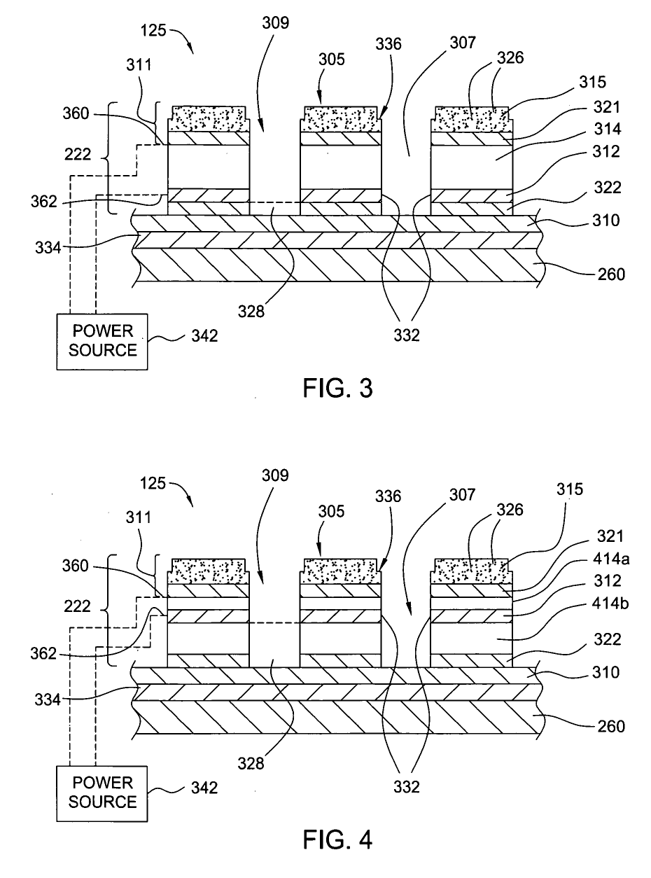

FIG. 3 is a schematic side view of a portion of one embodiment of a pad assembly 222. The pad assembly 222 comprises a processing surface 125, which includes a plurality of apertures 309 adjacent a plurality of discrete members 305 coupled to an upper surface of a pad base 310. Each of the plurality of discrete members 305 comprise a first conductive layer 311, a second conductive layer 312, with an isolation layer 314 therebetween. The second conductive layer 312 is coupled to a pad base 310 by a binding layer 322 which is an adhesive that is compatible with process chemistry, such as heat and/or pressure sensitive adhesives known in the art. Other layers of the pad assembly 222 may be coupled by a suitable adhesive. The pad assembly 222 is releasably coupled to the upper surface 260 of the platen assembly by a coupling layer 334 between the upper surface 260 and the lower surface of the pad base 310. The coupling layer 334 may be an adhesive, a hook and loop connector, or any other binder known in the art configured to provide static placement and facilitate replacement of the pad assembly 222.

The pad assembly 222 also includes a plurality of reaction surfaces 332 comprising the exposed sidewalls of the second conductive layer 312 in the plurality of apertures 309. Each of the reaction surfaces 332 are orthogonal to the pad base 310 and the upper surface of the pad assembly 222, and are configured to provide expanded electrochemical activity in each of the plurality of functional cells 307. A plurality of recesses 328 are defined by the area between the upper surface of the pad base 310 and the lower surfaces of each of the plurality of reaction surfaces 332 (generally shown as a dashed line).

In a typical ECMP polishing process, byproducts, such as materials removed from the deposit receiving side of the substrate and/or materials that are removed from the pad assembly 222 by contact with the substrate, tend to accumulate in a lower portion of the pad assembly 222. These byproducts may accumulate on or near the conductive layer performing as the cathode in the ECMP process, thus decreasing electrochemical activity and material removal from the substrate. It has been found that positioning the second conductive layer 312 in a spaced-apart relationship from the portions of the pad base 310 in the functional cells 307, may extend electrochemical activity by creating an area below the reaction surfaces 332 for byproduct accumulation. Each recess 328 may facilitate prolonged electrochemical activity in the functional cells 307 by allowing byproducts to accumulate away from the reaction surfaces 332, thus maintaining more stabile electrochemical activity within each of the plurality of functional cells 307. This consistent electrochemical activity may provide a higher removal rate, and/or an improved consistency in the removal rate, thus decreasing process time and increasing throughput.

FIG. 4 is a schematic side view of a portion of another embodiment of a pad assembly 222. The pad assembly 222 of FIG. 4 is similar to the pad assembly 222 depicted in FIG. 3 with the exception of a different placement of the second conductive layer. The pad assembly 222 of FIG. 4 comprises a processing surface 125, which includes a plurality of apertures 309 adjacent a plurality of discrete members 305 coupled to an upper surface of a pad base 310. The pad assembly 222 is releasably coupled to the upper surface 260 of the platen assembly by a coupling layer 334 between the upper surface 260 and the lower surface of the pad base 310. Each of the plurality of discrete members 305 comprise a first conductive layer 311, a first isolation layer 414a, a second conductive layer 312, and a second isolation layer 414b. The second isolation layer 414b is coupled to the pad base 310 by a binding layer 322 which is an adhesive that is compatible with process chemistry. Other layers of the pad assembly 222 may be coupled by a suitable adhesive. The pad assembly 222 of FIG. 4 also includes a plurality of reaction surfaces 332 comprising the exposed sidewalls of the second conductive layer 312 in the plurality of apertures 309. Each of the reaction surfaces 332 are orthogonal to a pad base 310 and the upper surface of the pad assembly 222, and are configured to provide expanded electrochemical activity in each of the plurality of functional cells 307. A plurality of recesses 428 are defined by the area between the upper surface of the pad base 310 and the lower surfaces of each of the plurality of reaction surfaces 332 (generally shown as a dashed line).

In the embodiments shown in FIGS. 3 and 4, the size of each of the plurality of recesses 328 may be varied. For example, the height of each recess 328 of the pad assembly 222 of FIG. 3 may be varied according to the thickness of the binding layer 322. The binding layer 322 is a pressure and/or temperature sensitive adhesive that is compatible with process chemistry and may be applied at a desired thickness. Alternatively, the aforementioned adhesive may be applied at a suitable thickness and allowed to cure before another suitable thickness is applied. In this manner, the binding layer 322 may be formed to a desired thickness that defines the height of the recesses 328. Similarly, in FIG. 4, the height of each recess 328 may be varied by the thickness of the second isolation layer 414b and/or the thickness of the binding layer 322 as in FIG. 3. In one embodiment, the plurality of recesses 328 are configured to facilitate stability and prolonged maintenance of electrochemical activity in each of the plurality of functional cells 307, by providing a plurality of functional cells 307 that resist deteriorated electrochemical activity from byproduct accumulation.

In FIGS. 3 and 4, the first conductive layer 311 comprises a conductive material 315 coupled to a conductive carrier 321. The conductive carrier 321 comprises a conductive material, such as stainless steel, aluminum, gold, silver, copper, tin, nickel, among others. For example, the conductive carrier 321 may be a metal foil, a mesh made of metal wire or metal-coated wire, or a laminated metal layer on a polymer material compatible with the electrolyte, such as a polyimide, polyester, fluoroethylene, polypropylene, or polyethylene sheet.

The conductive material 315 may comprise a conductive polymer material as described herein. In one embodiment, the conductive material 315 comprises a conventional polishing material, such as polymer based pad materials compatible with the process chemistry, examples of which include polyurethane, polycarbonate, fluoropolymers, PTFE, PTFA, polyphenylene sulfide (PPS), or combinations thereof. The conventional polishing material may be coated, doped, or impregnated with a process compatible conductive material and/or particles. Alternatively, the conductive material 315 may be a conductive polymer, such as a conductive filler material disposed in a conductive polymer matrix, such as fine tin particles in a polyurethane binder, or a conductive fabric, such as carbon fibers in a polyurethane binder.

In one embodiment, the conductive material 315 comprises removal particles 326 adapted to facilitate material removal from the deposit receiving side of the substrate. In one embodiment, the removal particles 326 are conductive particles, such as particles of tin, copper, nickel, silver, gold, or combinations thereof, in a conductive polymer matrix. In another embodiment, the removal particles 326 are abrasive particles, such as aluminum, ceria, oxides thereof and derivatives thereof, and combinations thereof, in a conductive polymer matrix. In yet another embodiment, the removal particles 326 are a combination of abrasive and conductive particles as described herein and are interspersed within the conductive material 315. The conductive material 315 may further include an edge region 336 on at least one side of the upper portion of the first conductive layer 311. The edge region 336 may be a chamfer, a bevel, a square groove, or combinations thereof, and are adapted to facilitate electrolyte and polishing byproduct transportation.

The conductive carrier 321 and the second conductive layer 312 are electrically isolated from each other by a dielectric isolation layer 314 and 414a. As seen in FIG. 4, the pad assembly 222 has two isolation layers 414a and 414b. The isolation layers depicted in FIGS. 3 and 4 may have a hardness of about 20 Shore A to about 90 Shore A and may be fabricated from polymeric materials, such as polyurethane and polyurethane mixed with fillers, polycarbonate, polyphenylene sulfide (PPS), ethylene-propylene-diene-methylene (EPDM), Teflon™ polymers, or combinations thereof, and other polishing materials used in polishing substrate surfaces, such as open or closed-cell foamed polymers, elastomers, felt, impregnated felt, plastics, and like materials compatible with the processing chemistries. In one embodiment, the isolation layers comprise open cell foam to enhance electrolyte retention, such as a urethane material sold under the trade name PORON®, which is available from the Rogers Corporation. In another embodiment in reference to FIG. 4, the first isolation layer 414a may be a softer, more compliant material, while the second isolation layer 414b may be harder to provide additional support, or vice versa.

The second conductive layer 312 may be fabricated from a conductive material, such as stainless steel, aluminum, gold, silver, copper, tin, nickel, among others. For example, the second conductive layer 312 may be a metal foil, a mesh made of metal wire or metal-coated wire, or a laminated metal layer on a polymer material compatible with the electrolyte, such as a polyimide, polyester, flouroethylene, polypropylene, or polyethylene sheet. In one embodiment, the second conductive layer 312 is configured to provide conformity and sufficient stiffness to allow the pad assembly to remain substantially flat alone, or in combination with the pad base 310. Each of the first and second conductive layers 311, 312 include at least one connector 360, 362 respectively, for coupling to one or more power sources adapted to supply a differential electrical signal to each of the first and second conductive layers. Each of the at least one connectors 360, 362 may be made of a conductive material and coupled to the pad assembly 222 by any methods known in the art, such as soldering, adhesives, or combinations thereof, or integrally formed on the pad assembly. For example, a first connector 360 may be coupled to the pad assembly by a conductive adhesive, while a second connector 362 is integrally formed on the second conductive layer 312. Each of the at least one connectors 360, 362 may be made from nickel, copper, tin, stainless steel, platinum, gold, silver, or combinations thereof.

In one embodiment, each of the first and second conductive layers 311, 312 are adapted to couple to a power source 342 that is adapted to supply different electrical voltages to each of the first and second conductive layers. The second conductive layer 312 may provide one electrical signal that is distributed globally within the respective layer, or may comprise multiple independent electrical zones isolated from each other. The independent zones receive separate and independent voltages and adjacent zones are insulated from each other in order to provide varying voltages to specific portions of the respective layer.

The pad base 310 facilitates support of the pad assembly 222 and is typically made of a material harder or denser relative to other layers of the pad assembly 222. The pad base 310 may exhibit a stiffness high enough to allow the pad assembly 222 to remain substantially flat and low enough to ensure conformability of other layers of the pad assembly. The pad base 310 may be made of a sheet or film of a polyurethane, polycarbonate, polyphenylene sulfide (PPS), ethylene-propylene-diene-methylene (EPDM), TEFLON® polymers, or combinations thereof, and other polymer materials compatible with the processing chemistries. In one embodiment, the pad base 310 is a polyethylene terephthalate (PET) material, or derivatives thereof, such as a MYLAR® polymer. The PET material has a density between about 1.25 grams/cm² to about 1.45 grams/cm² and a modulus of elasticity between about 700,000 psi to about 760,000 psi. The pad base 310 material may have a hardness of about 30 Shore A to about 90 Shore A, and is typically harder than the isolation layers. The pad base 310 may be fabricated in any geometrical form, such as rectangular or circular, in order to facilitate coupling to the upper surface 260 of the platen assembly.

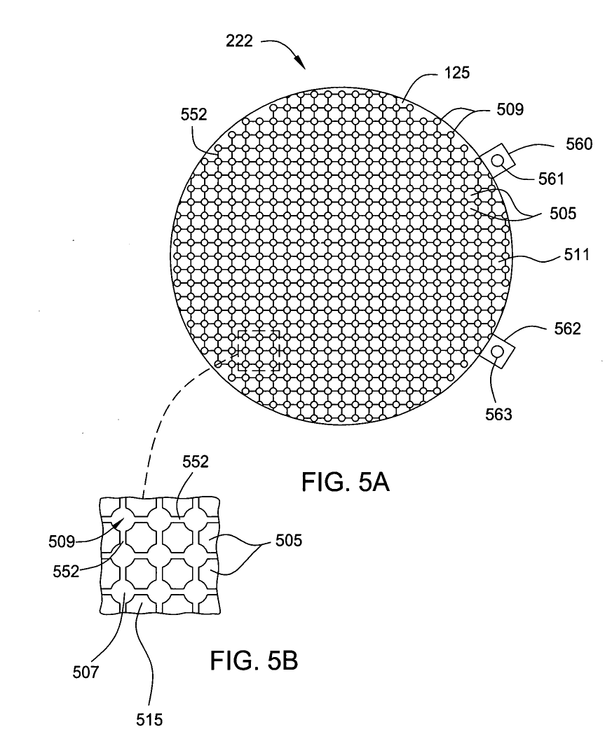

FIG. 5A is a top view of another embodiment of a pad assembly 222. The pad assembly 222 is exemplarily shown here as circular and comprises a processing surface 125. The processing surface 125 includes a plurality of discrete members 505 adjacent a plurality of apertures 509. Each of the discrete members 505 are made of a conductive material 515 as described herein. Also shown is a first connector 560 coupled to the first conductive layer 511 and a second connector 562 coupled to the second conductive layer (not visible in this view). The first and second connectors 560, 562 include a hole 561, 563 respectively, for coupling to a mating electrical connection on the platen assembly (not shown) and may also facilitate coupling of the pad assembly 222 to the platen assembly.

FIG. 5B is an exploded view of a portion of the processing surface 125 of the pad assembly 222 shown in FIG. 5A. A plurality of apertures 509 are interspersed within a plurality of discrete members 505. Each of the plurality of apertures 509 comprise a functional cell 507 as described herein. Each of the plurality of apertures 509 are surrounded by a plurality of channels 552. In one embodiment, the plurality of channels 552 are formed from the edge regions 336 (FIGS. 3 and 4). In another embodiment, the plurality of channels 552 may be formed in the conductive material 515 by such methods as embossing or compression molding. The channels 552 may be formed of and comprised solely of the conductive material 515, or the channels 552 may be formed down to the conductive carrier (not shown), thereby exposing the upper surface of the conductive carrier.

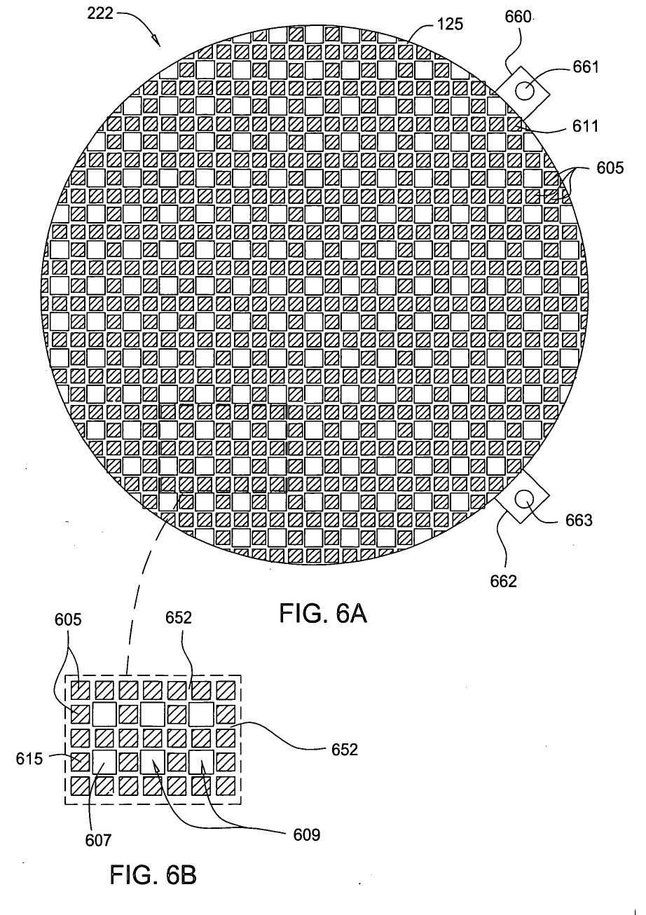

FIG. 6A is a top view of another embodiment of a pad assembly 222. The pad assembly 222 is exemplarily shown here as circular and comprises a processing surface 125. The processing surface 125 includes a plurality of discrete members 605 adjacent a plurality of apertures 609. The surface area occupied by each of the plurality of apertures 609 may be greater than, less than, or equal to the surface area of each of the plurality of discrete members 605. Each of the discrete members 605 are made of a conductive material 615 as described herein. Also shown is a first connector 660 coupled to the first conductive layer 611 and a second connector 662 coupled to the second conductive layer (not visible in this view). The first and second connectors 660, 662 include a hole 661, 663 respectively, for coupling to a mating electrical connection on the platen assembly (not shown) and may also facilitate coupling of the pad assembly 222 to the platen assembly.

FIG. 6B is an exploded view of a portion of the processing surface 125 of the pad assembly 222 shown in FIG. 6A. A plurality of apertures 609 are interspersed within a plurality of discrete members 605. Each of the plurality of apertures 609 comprise a functional cell 607 as described herein. Each of the plurality of apertures 609 are surrounded by a plurality of channels 652. The pattern of channels 652 and discrete members 605 is an x-y pattern in this embodiment, but other patterns may be formed. In one embodiment, the channels 352 are formed from the edge regions 336 (FIGS. 3 and 4). In another embodiment, the channels 652 may be formed in the conductive material 615 by such methods as embossing or compression molding. The channels 652 may be formed of and comprised solely of the conductive material 615, or the channels 652 may be formed down to the conductive carrier (not shown), thereby exposing the upper surface of the conductive carrier.

While the foregoing is directed to the illustrative embodiment of the present invention, other and further embodiments of the invention may be devised without departing from the basic scope thereof, and the scope thereof is determined by the claims that follow.

1. A pad assembly for processing a substrate, comprising:
a first conductive layer having an upper surface adapted to contact the substrate;
a conductive carrier coupled to and disposed below the first conductive layer;
a second conductive layer disposed below the conductive carrier with an isolation layer therebetween, wherein the second conductive layer includes a plurality of reaction surfaces that are orthogonal to the upper surface; and
a plurality of recesses formed below the second conductive layer.

2. The pad assembly of claim 1, further comprising:
a pad base disposed below the second conductive layer with a binding layer therebetween.

3. The pad assembly of claim 1, wherein the first conductive layer further comprises a plurality of removal particles.

4. The pad assembly of claim 3, wherein the plurality of removal particles are conductive metal particles.

5. The pad assembly of claim 3, wherein the plurality of removal particles are abrasive particles.

6. The pad assembly of claim 1, wherein the pad assembly has a plurality of functional cells.

7. The pad assembly of claim 6, wherein the plurality of functional cells define an open area of between about 10 to about 90 percent.

8. The pad assembly of claim 1, wherein the second conductive layer is made of copper, titanium, tin, nickel, or stainless steel.

9. The pad assembly of claim 2, wherein the one of the pad base or the second conductive layer has a stiffness low enough to ensure conformability and remain substantially flat.

10. The pad assembly of claim 1, wherein one or both of the conductive carrier and the second conductive layer is made of a metal foil.

11. The pad assembly of claim 1, wherein one or both of the conductive carrier and the second conductive layer is made of a mesh comprised of metal wire or metal-coated wire.

12. A pad assembly for processing a substrate, comprising:
a plurality of discrete members coupled to a base defining a plurality of functional cells therebetween; and,
a bonding layer to adhere a second conductive layer to the base to define a recess above the base, wherein each of the plurality of discrete members include a first conductive layer adapted to contact the substrate and the second conductive layer separated by an isolation layer with a plurality of recesses formed below the second conductive layer.

13. The pad assembly of claim 12, wherein the second conductive layer includes a plurality of reaction surfaces.

14. The pad assembly of claim 12, wherein the plurality of reaction surfaces are orthogonal to the base.

15. The pad assembly of claim 12, wherein the first conductive layer further comprises:
a conductive composite coupled to a conductive carrier.

16. The pad assembly of claim 15, wherein the conductive composite includes a plurality of removal particles and the plurality of removal particles are abrasive particles, conductive particles, or combinations thereof.

17. The pad assembly of claim 15, wherein the conductive composite includes a plurality of intersecting channels.

18. A pad assembly for polishing a substrate, comprising:
a processing surface adapted to contact the substrate, the processing surface comprising:
a plurality of discrete members defining a plurality of functional cells therebetween; wherein each of the plurality of discrete members include a first conductive layer and a second conductive layer with an isolation layer therebetween, and wherein the second conductive layer comprises a plurality of reaction surfaces that are orthogonal to the processing surface.

19. The pad assembly of claim 18, wherein each of the plurality of discrete members are coupled to a pad base and a recess for byproduct accumulation is formed above the pad base.

20. The pad assembly of claim 18, wherein the processing surface further comprises:
a plurality of channels.

21. The pad assembly of claim 18, further comprising:
at least one connector coupled to the pad assembly.

22. A method of extending electrochemical activity in a processing pad assembly, comprising:
providing a pad assembly having a first conductive layer, a second conductive layer, and a plurality of functional cells; and
providing a recess below the second conductive layer for by-product accumulation from a polishing process.

23. The method of claim 22, wherein the second conductive layer includes a plurality of reaction surfaces within the functional cells.

24. The method of claim 23, wherein the recess is below each reaction surface.

25. The method of claim 23, wherein the polishing by-products accumulate below the second conductive layer allowing each reaction surface to remain substantially free from the polishing by-products.
